(19) United States
(12) Patent Application Publication
(10) Pub. No.: US 2016/0380418 A1
(43) Pub. Date: Dec. 29, 2016

(54) DEVICE FOR RECEIVING A CABLE HARNESS

(71) Applicant: NEXANS, Paris (FR)

(72) Inventors: Thomas Kreuzer, Neustadt a.d. Waldnaab (DE); Erhard Walter, Georgenberg (DE)

(21) Appl. No.: 15/190,419

(22) Filed: Jun. 23, 2016

(30) Foreign Application Priority Data
Jun. 26, 2015 (EP) 15 306 012.4

(51) Int. Cl. H02G 3/08; H05K 7/14; H05K 5/02

(52) U.S. Cl. CPC H02G 3/083; H05K 5/0247; H05K 7/1401

(57) ABSTRACT

A device for receiving at least one cable harness is indicated, which has a housing composed of mechanically stable insulation material, on which at least one ring shaped undulated pipe is attached, that in the mounted position, is secured in an opening of the housing. In the mounted position, a bolder composed of combinable parts guided through an opening in the wall of the housing by which each two parts in the combined state with dimensions to be secured in the opening of the housing, ring shaped undulated pipes, a corresponding central passage locked therebetween, is attached. In the mounted position each two parts of the holder engage with two sides of the pipe lying diametrically opposite each other, in at least one trough of the ring shaped undulation of the same.

### RELATED APPLICATION

This application claims the benefit of priority from European Patent Application. No. 15 306 012.4, filed on Jun. 26, 2015, the entirety of which is incorporated by reference.

### BACKGROUND

Field of the Invention

The invention relates to a device for receiving at least one cable harness which includes a housing composed of a mechanically stable insulation material, which is attached to at least one ring shaped undulated pipe composed of synthetic material that, in the mounted position, is secured in an opening of the housing (DE 10 2007 035 539 B4).

Description of Related Art

The housing of such a device is, for example, as customary in automobile technology, that the cable duct accepts one of the many cable harnesses composed of electrical conductors or cable trees. A housing can, however, also be a switch housing or a connection sleeve or another device, to which an electrical conductor arranged in an undulated pipe is attached, and as a result the pipe will be guided into the housing. Such a housing as a rule, composed of a top part and a bottom part, is for example, manufactured by injection molding, which provides for installing suitable undulated pipe openings.

The above mentioned DE 10 2007 035 539 B4 discloses a housing of synthetic material for receiving at least one cable harness, which is composed of two parts separated from each other along a separating plane. The housing forms a pipe shaped form, also along the separating plane, in two-part separated supports to secure a ring shaped undulated pipe composed of synthetic material that serves for the receiving of electrical lines.

The separating plane and the axis of the moveable part consisting of an associated rigid part composed of supports connected tightly to a corresponding part of the housing, passes under an acute angle to the separating plane of the housing.

### OBJECTS AND SUMMARY

The invention is based on the object of simplifying the construction of the above mentioned device.

The object is met in accordance with the invention in,
that in the opening of the housing, in the mounted position, a holder, composed of combinable parts, in which each two parts in the combined state with dimensions to be secured in the opening of the housing, ring shaped undulated pipes, a corresponding central passage locked therebetween, is attached, and
that each of the two parts of the holder engage, in the mounted position, on two sides of the pipe lying diametrically opposite each other in at

The housing of this device is composed advantageously of two parts, a top part or cover and a bottom part, that in the mounted position, is connected to a one-part housing. By the manufacture of the two parts of the housing at least one opening is advantageously generated in the wall of the bottom part, which is open on the upper edge. The opening has advantageously a rectangular cross section. A holder is provided for mounting a ring shaped undulated pipe on the housing, which as a ready holder has a passage for the pipe. The size and form of the opening in the bottom part of the housing is not dependent on the diameter of an undulated pipe to be attached therein. The production of the housing overall can thereby essentially be simplified and the housing may be used for undulated pipes with different diameters. It must be ensured in each case that a conforming holder is provided in the opening. The parts are guided each in the opening delimiting walls of the bottom part.

When two undulated pipes should be mounted next to each other in only one opening, the holder can advantageously be composed of three parts combined together. A middle part of the holder has a half passage on two opposite sides, which are each added from both outer parts of the holders to two complete passages to receive the two undulated pipes.

### BRIEF DESCRIPTION OF THE DRAWINGS

Embodiments of the present subject matter are illustrated in the drawings:

In the drawings:

FIG. 1 shows a schematic illustration of a housing for the device according to the invention.

FIG. 2 shows a side view of the housing according to FIG. 1, also in a schematic illustration.

FIG. 3 shows an opening for the housing of the device.

FIG. 4 shows an insertable holder in the opening according to FIG. 3.

FIGS. 5 and 6 show an insertable holder in the opening according to FIG. 3.

FIGS. 7 and 8 show two different complete holders opposite to FIG. 4.

### DETAILED DESCRIPTION

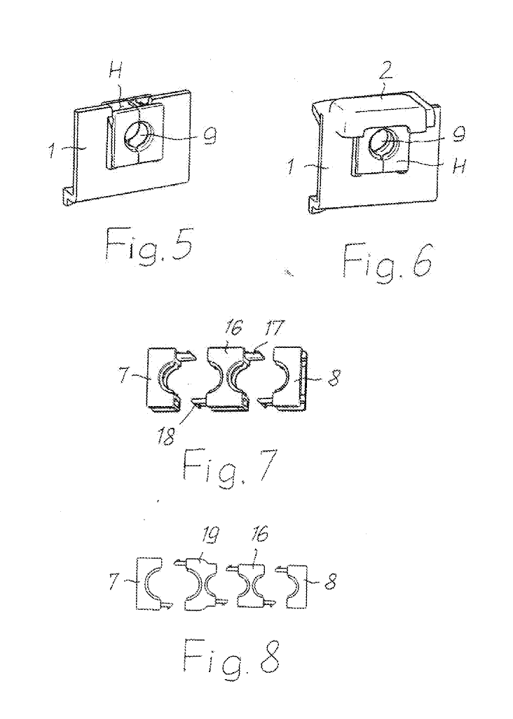

For simplicity and clarity's sake, to secure the device in the housing the undulated pipe to be fastened in the housing is not included in the illustration in FIGS. 5 and 6.

FIG. 1 schematically illustrates a housing G composed of a bottom part 1 and a top part 2 which serve to receive and push through or divide a cable harness 3 containing a plurality of lines. The housing G is composed of synthetic material, such as for example, polypropylene or polyamide. The bottom part is advantageously constructed in the form of a trough and the top part is advantageously a cover, that when the closed housing G is placed on the bottom part 1 it is connected to the same.

In the bottom part 1 of the housing G an opening 4 is provided, in the mounted position a pipe 5, which is undulated ring shaped, is secured also of synthetic material, composed of for example, polypropylene or polyamide. In the pipe 5 a cable harness 6 is received which is guided into the housing G. The opening 4 of the bottom part 1 advantageously has, according to FIG. 3, a rectangular internal cross section. It protrudes up to the upper edge of the bottom part 1 and is open towards the outside.

As illustrated in FIG. 4, to secure the pipe 5 in the opening 4 a holder H of two parts 7 and 8 can be used which has a passage 9 (FIG. 5) to receive the pipe 5. The holder H shown in FIG. 5 is then completed when both the parts 7 and 8 are joined. They can then advantageously be equipped with latching elements 10 and 11. In each of the two parts 7 and 8 is formed a half of the passage 9 so that the joined parts 7 and 8 surround the closed passage 9 as a result.

In the illustrated embodiment, the parts 7 and 8 of the holder H have on their bent extending, delimiting sides of the passage 9 on the closed pipe 5—two ribs 13 and 14 circumferentially extending at a distance parallel to each other.

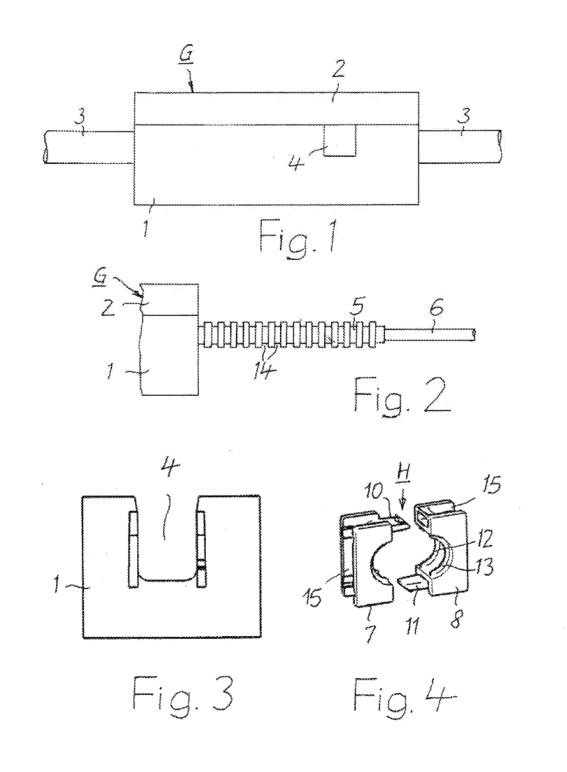

In the mounted position the ribs 13 and 14 engage in two nearby troughs 14 (FIG. 2) of the undulated pipes. The holder H should have at least one of this type of rib. The parts 7 and 8 of the holder H have on their outer edges continuous groove shaped indentations 15, which equal the width of the thickness of the walls of the bottom part 1 of the housing G.

After completion of the mounting, when the halter H is laid around an undulated pipe 5 and placed in the opening 4 can the top part 2 of the housing G be placed on the bottom part 1, according to FIG. 6. The holder H and the surrounding undulated pipe 5 are then secured in the housing G.

Securing the pipe 5 on or in the housing G is carried out as follows, for example:

Both parts 7 and 8 of the holder H are arranged on the end of the ring shaped undulated pipe 5 placed against the pipe coming from two sides lying opposite each other and moved toward each other until they are connected through the latching elements 10 and 11. In this position the ribs 12 and 13 engage the parts 7 and 8 in two neighboring troughs 14 of the pipe 5. The completed holder H can then be placed, together with the surrounded pipe 5, in the opening 4 of the bottom part 1 of the housing G. Thereby, the halter H is guided through its groove shaped indentations 15 from the delimiting walls of the opening 4 of the bottom part 1 of the housing G. The end position of the holder H is shown in FIG. 5. Finally, the top part 2 is placed on the bottom part 1 of the housing G, as illustrated in FIG. 6. Before mounting, the pipe 5 can be pushed on the cable harness 6.

An alternative to the description of the mounting of the holder H, also initially the part 7 of the holder H can be placed in the opening 4 in the bottom part 1 of the housing G, so that the bent extending side faces upwardly. Initially, the part 7 is guided from the wails of the bottom part 1 which engages in the groove formed indentations 15 of the same. After, the pipe 5 with its one end can be so placed on the part 7 that the ribs 12 and 13 engage in two troughs of the pipe 5. Finally, the part 8 of the holder H is placed in the opening 4 of the bottom part 1 and guided through the walls of the same, pushed so far down until the ribs 12 and 13 engage in the same trough 14 of the pipe 5 as they engage part 7. In the end position the parts 7 and 8, joined to each other, would be connected to the holder H through the flexible latching elements 10 and 11. This end position is then illustrated in FIG. 5.

When two ring shaped undulated pipes 5 would be arranged in an opening 4 of the housing a corresponding complete Halter H, illustrated in FIG. 7, can be used, which can be placed in a matching larger opening 4. This holder H is composed of parts 7 and 8 and a middle part 16, which in the mounted position is connected to the two parts 7 and 8. This can also be effected by latching elements 17 and 18. Between the three parts 7, 8 and 16 this holder H in the mounted position has two passages 9 available.

A further complete holder H can be used to arrange from three pipes in corresponding large openings in the bottom part 1 of the housing G as illustrated in FIG. 8. This holder H has a second middle part 19 which corresponds to the construction of the middle part 16, according to FIG. 7.

1. A device for receiving at least one cable harness comprising:
a housing composed of a mechanically stable insulation material, for mounting at least one ring shaped undulated pipe composed of synthetic material that, in an opening of the housing,
wherein, in the opening of the housing, in the mounted position, a holder is composed of two combinable parts, that in the combined state have dimensions for securing within said opening of the housing, said ring shaped undulated pipe, within a corresponding central passage of said parts, and
wherein each of the two parts of the holder engage, in the mounted position, on two sides of the pipe, lying diametrically opposite each other, in at least one trough of the ring shaped undulation of said pipe.

2. Device according to claim 1, wherein the parts of the holder, in the mounted position, are releasably connected with each other by locking elements.

3. Device according to claim 1, wherein the parts of the holder have at least one rib which in the mounted position engages in a trough of the ring shaped undulated pipe.

4. Device according to claim 1, wherein through fastening two or more ring shaped undulated pipes lying next to each [symbol]
